(19) United States
(12) Patent Application Publication
(10) Pub. No.: US 2024/0274658 A1
(43) Pub. Date: Aug. 15, 2024

(54) SUPER JUNCTION DEVICE AND METHOD FOR MANUFACTURING THE SAME

(71) Applicant: Shanghai Huahong Grace Semiconductor Manufacturing Corporation, Shanghai (CN)

(72) Inventor: Hao LI, Shanghai (CN)

(21) Appl. No.: 18/569,635

(22) PCT Filed: Oct. 12, 2022
(86) PCT No.: PCT/CN2022/124750

§ 371 Date: Dec. 13, 2023

(30) Foreign Application Priority Data
Oct. 20, 2021 (CN) 202111219427.7

(51) Int. Cl. H01L 29/06; H01L 21/265; H01L 21/266; H01L 29/66; H01L 29/78

(52) U.S. Cl. CPC H01L 29/0634; H01L 21/26513; H01L 21/266; H01L 29/66734; H01L 29/7813

(57) ABSTRACT

The invention is a super junction device, with a gate structure of a device unit region having a trench gate and having a depth of the gate trench that is greater than the junction depth of a P-type body region. The top surface of the gate trench is level with the top surface of a super junction unit, and the top surface of a polysilicon gate is etched back below the top surface of the gate trench. A source region is formed on the side surface of the gate trench on the top of the polysilicon gate and on the surface of the P-type body region outside the gate trench. A length of a channel is controlled by controlling the position of the top surface of the polysilicon gate so as to control gate-source capacitance. The invention includes a method for manufacturing the super junction device.

### CROSS-REFERENCES TO RELATED APPLICATIONS

This application is a national stage patent application filing of International Application No. PCT/CN2022/124750, filed Oct. 12, 2022, which claims the priority to Chinese patent application No. CN 202111219427.7, filed on Oct. 20, 2021, and entitled “SUPER JUNCTION DEVICE AND METHOD FOR MANUFACTURING THE SAME”, the disclosure of which is incorporated herein by reference in entirety.

### TECHNICAL FIELD

The present application relates to the field of semiconductor integrated circuit manufacturing, in particular to a super junction device. The present application also relates to a method for manufacturing a super junction device.

### BACKGROUND

A super junction is composed of P-type films, also referred to as P-type pillars, and N-type films, also referred to as N-type pillars, which are arranged alternately and formed in a semiconductor substrate. A device provided with the super junction is a super junction device, for example, a super junction MOSFET. The internal reduced surface field (Resurf) technology utilizing a charge balance between the P-type film and the N-type film can increase the reverse breakdown voltage of the device while maintaining a relatively small on-resistance.

A pillar structure with alternating PN of the super junction is the most significant feature of the super junction. There are currently two main methods for manufacturing the alternately arranged pillar structure of PN. In one method, the pillar structure is obtained by means of multiple times of epitaxy and ion implantation, and in the other method, the pillar structure is manufactured by means of deep trench etching and epitaxial (EPI) filling. In the latter method, a super junction device is manufactured by means of a trench process, including first etching a trench of certain depth and width on an N-type doped epitaxial layer on the surface of a semiconductor substrate such as a silicon substrate, and then filling the etched trench with P-type doped silicon epitaxial layer by means of epitaxial filling (EPI Filling).

In the manufacturing of the super junction using the deep trench, i.e., the super junction trench etching and epitaxial filling processes, due to the impact of an epitaxial layer step such as step silicon near the surface of the super junction trench, defects are easy to occur in bulk silicon close to the surface, leading to a leakage failure of the device.

In the existing method, a P-type body region is formed in a super junction device such as a super junction MOSFET, and the P-type body region is formed by means of ion implantation and annealing drive-in after trench filling of the super junction. The bottom of the P-type body region is an N-type drift region corresponding to the N-type pillar, and a body diode is formed between the P-type body region and the N-type drift region. By increasing the depth of the P-type body region, most of the surface defects can be excluded from the depletion region, thereby greatly alleviating the device leakage. That is, a relatively deep P-type body region is required for eliminating the adverse effects brought by the surface defects of the super junction.

In the super junction device, the surface of the P-type body region is usually used to form a channel, and in particular, the surface of the P-type body region covered by a gate structure is used to form the channel. Due to the complicated manufacturing process of the pillar structure, i.e., the P-type pillar and the N-type pillar, of the super junction, the gate structure is usually formed after the manufacturing of the pillar structure, and the manufacturing process of the body region is performed after the formation of the gate structure. The existing process of first forming the pillar structure of the super junction, then forming the gate structure, and then forming the P-type body region has the following contradictions:

A deep P-type body region is required for eliminating the adverse effects of the surface defects of the super junction, and the deep P-type body region requires a large thermal process, that is, the thermal annealing drive-in requires high temperature and long time. However, after the pillar structure is formed, a large thermal process is undesired, because the large thermal process may cause interdiffusion and mutual compensation of impurities of the P-type pillar and the N-type pillar in the pillar structure, reducing the net doping concentration, and thereby leading to a significant degradation of the device performance.

In a previous patent application No. CN2020100690252 filed by the applicant, the applicant disclosed that a P-type body region is formed by superimposing a first P-type doped region and a second P-type doped region, so as to avoid the adverse effect of the annealing drive-in thermal process of the body region on the performance of the super junction in the case of a relatively deep P-type body region, without affecting the threshold voltage of the device.

However, in a trench gate super junction device, with the increase of the junction depth of the body region, the area of the junction covered by the side of the trench gate increases, and the parasitic capacitance, i.e., gate-source capacitance, caused by the deep junction of the body region also increases. The increase of the gate-source capacitance may improve both the switching softness and EMI characteristics of the device.

However, in some cases of a higher switching frequency, the large gate-source capacitance brings a large switching loss, leading to a decrease in the system efficiency. Therefore, the magnitude of the gate-source capacitance needs to be adjusted according to application cases. In some cases, the magnitude of the gate-source capacitance defined by the junction depth of the body region cannot satisfy the requirements of the application cases.

### BRIEF SUMMARY

The technical problem to be solved by the present application is to provide a super junction device, in which length adjustment of a channel is independent of depth adjustment of a body region, so that gate-source capacitance of the device can be controlled by adjusting the length of the channel, and adverse effects brought by surface defects of a super junction can be eliminated by increasing the depth of the body region, thereby improving a product yield. To this end, the present application further provides a method for manufacturing a super junction device.

According to some embodiments in this application, a device unit region of the super junction device provided by the present application includes:

a super junction composed of P-type pillars and N-type pillars arranged alternately, one of the P-type pillars and an adjacent N-type pillar forming a super junction unit.

The P-type pillar is formed by a P-type epitaxial layer filling a super junction trench, the N-type pillar is formed by a first N-type epitaxial layer located between the P-type pillars, and the super junction trench is formed in the first N-type epitaxial layer; a P-type body region is formed in the first N-type epitaxial layer.

Each super junction device unit further includes a gate structure, the gate structure being a trench gate including a gate trench, a gate dielectric layer formed on the inner surface of the gate trench, and a polysilicon gate filling the gate trench.

At least one side surface of the gate trench is located in the N-type pillar, and the depth of the gate trench is greater than the junction depth of the P-type body region.

The top surface of the gate trench is level with the top surface of the super junction unit, and the top surface of the polysilicon gate is etched back below the top surface of the gate trench.

A source region is formed by an N+ doped region which is formed by performing ion implantation on the side surface of the gate trench on the top of the polysilicon gate and on the surface of the P-type body region outside the gate trench.

The surface of the P-type body region at the bottom of the source region and covered by the side surface of the polysilicon gate is used to form a channel, the length of the channel is controlled by controlling the position of the top surface of the polysilicon gate so as to control gate-source capacitance, and a larger distance between the top surface of the polysilicon gate and the top surface of the gate trench corresponds to a shorter channel and smaller gate-source capacitance.

In some cases, the P-type body region is formed by superimposing a first P-type doped region and a second P-type doped region, so as to increase the junction depth of the P-type body region.

The first P-type doped region is formed by means of ion implantation and annealing drive-in before the P-type pillar is formed, the doping concentration and depth of the first P-type doped region are determined by corresponding ion implantation and annealing drive-in processes, and the annealing drive-in process of the first P-type doped region is not limited by process conditions of the super junction including the P-type pillar such that the depth of the first P-type doped region can be increased, thereby increasing the junction depth of the P-type body region.

Before the polysilicon gate is etched back, under the condition that the top surface of the polysilicon gate is level with the top surface of the gate trench, the second P-type doped region is formed in the first P-type doped region on two sides of the gate structure by means of full ion implantation in a self-aligned manner, the full ion implantation for forming the second P-type doped region being used to adjust a threshold voltage for forming the channel.

In some cases, a terminal region of the super junction device is formed on the periphery of the device unit region; the terminal region includes a P-type ring surrounding the device unit region, the first P-type doped region and the P-type ring have the same doped structure and are simultaneously formed by means of the same ion implantation and annealing drive-in processes, and the junction depth of the P-type body region is 1-5 micrometers.

In some cases, the first N-type epitaxial layer is formed on the surface of a semiconductor substrate.

In some cases, the semiconductor substrate is a silicon substrate, the first N-type epitaxial layer is a silicon epitaxial layer, and the P-type epitaxial layer of the P-type pillar is a silicon epitaxial layer.

In some cases, an N+ doped drain region is formed at the bottom of the first N-type epitaxial layer, and the drain region is formed by the thinned N+ doped semiconductor substrate or formed by performing N+ back ion implantation on the thinned semiconductor substrate.

In some cases, an implantation dose of the ion implantation for forming the first P-type doped region is greater than 2e13 cm⁻², and the junction depth of the P-type body region is 3 micrometers.

In order to solve the above technical problem, in the method for manufacturing a super junction device provided by the present application, steps of forming a device unit region of the super junction device includes:

step 1, forming a super junction trench in a first N-type epitaxial layer, filling the super junction trench with a P-type epitaxial layer to form a P-type pillar, the first N-type epitaxial layer located between the P-type pillars forming an N-type pillar, the P-type pillars and the N-type pillars being arranged alternately to form a super junction, and one of the P-type pillars and an adjacent N-type pillar forming a super junction unit;

step 2, forming a P-type body region in the first N-type epitaxial layer;

step 3, forming a gate structure corresponding to each super junction device unit, the gate structure being located on the top of the corresponding super junction unit, the gate structure being a trench gate, and sub-steps of forming the gate trench including:

step 31, forming the gate trench, at least one side surface of the gate trench being located in the N-type pillar, the depth of the gate trench being greater than the junction depth of the P-type body region, and the top surface of the gate trench being level with the top surface of the super junction unit;

step 32, forming a gate dielectric layer on the inner surface of the gate trench;

step 33, filling the gate trench with a polysilicon gate, the top surface of the polysilicon gate being level with the top surface of the gate trench;

step 34, forming a mask layer pattern to define a formation region of a source region, each gate trench being located in the formation region of the source region; and

step 35, etching back each polysilicon gate by using the mask layer pattern as a mask such that the top surface of the polysilicon gate is lower than the top surface of the gate trench, the gate dielectric layer and the polysilicon gate filling the gate trench being superimposed to form the trench gate; and

step 4, performing N+ ion implantation to form a source region on the side surface of the gate trench on the top of the polysilicon gate and on the surface of the P-type body region outside the gate trench.

The surface of the P-type body region at the bottom of the source region and covered by the side surface of the polysilicon gate is used to form a channel, the length of the channel is controlled by controlling the position of the top surface of the polysilicon gate so as to control gate-source capacitance, and a larger distance between the top surface of the polysilicon gate and the top surface of the gate trench corresponds to a shorter channel and smaller gate-source capacitance.

In some cases, the P-type body region is formed by superimposing a first P-type doped region and a second P-type doped region, so as to increase the junction depth of the P-type body region; the step of forming the P-type body region in step 2 is divided into:

performing ion implantation and annealing drive-in to form the first P-type doped region before the formation of the super junction trench in step 1, and adjusting the doping concentration and depth of the first P-type doped region by means of ion implantation and annealing drive-in processes, the annealing drive-in process of the first P-type doped region being not limited by process conditions of the super junction including the P-type pillar such that the depth of the first P-type doped region can be increased, thereby increasing the junction depth of the P-type body region.

After step 33 and before step 34, full ion implantation is performed to form the second P-type doped region in the first P-type doped region on two sides of the gate structure in a self-aligned manner.

In some cases, a terminal region of the super junction device is formed on the periphery of the device unit region; and the terminal region includes a P-type ring surrounding the device unit region.

The first P-type doped region and the P-type ring are simultaneously formed by means of the same ion implantation and annealing drive-in processes; and the junction depth of the P-type body region is 1-5 micrometers.

In some cases, the first N-type epitaxial layer is formed on the surface of a semiconductor substrate.

In some cases, the semiconductor substrate is a silicon substrate, the first N-type epitaxial layer is a silicon epitaxial layer, and the P-type epitaxial layer of the P-type pillar is a silicon epitaxial layer.

In some cases, an implantation dose of the ion implantation for forming the first P-type doped region is greater than 2e13 cm⁻², and the junction depth of the P-type body region is 3 micrometers.

In some cases, the method further includes a step of forming an N+ doped drain region at the bottom of the first N-type epitaxial layer.

The drain region is directly formed by thinning the N+ doped semiconductor substrate.

Or, the drain region is formed by thinning the semiconductor substrate and then performing N+ back ion implantation on the thinned semiconductor substrate.

In some cases, in step 32, the gate dielectric layer is a gate oxide layer formed by means of a thermal oxidation process.

In the present application, the top surface of the polysilicon gate is etched back below the top surface of the gate trench and the source region is formed on the side surface of the gate trench on the top of the polysilicon gate and on the surface of the P-type body region outside the gate trench in a self-aligned manner, so that the length of the channel can be controlled by adjusting the position of the top surface of the polysilicon gate. When the device is turned on, a channel composed of an inversion layer may be formed on the surface of the body region covered by the side surface of the polysilicon gate, since the channel length is a height of the area of the body region covered by the side surface of the polysilicon gate, the channel length will also decrease when height of the area of the body region covered by the side surface of the polysilicon gate decreases. Since the source region and the body region of the device are usually connected to the source, the polysilicon gate is connected to the gate. Therefore, when the area of the body region covered by the side surface of the polysilicon gate decreases, the parasitic capacitance between the gate and the source, i.e., the gate-source capacitance, decreases.

In an existing device, the polysilicon gate usually passes through the body region completely, so the polysilicon gate may fully cover the entire depth of the body region, in which case a deeper depth of the body region corresponds to larger gate-source capacitance. In the present application, the channel length is achieved by etching back the polysilicon gate, so that the adjustment of the channel length can be independent of the adjustment of the depth of the body region. Therefore, the gate-source capacitance of the device can be controlled by adjusting the channel length, that is, even if the body region has a relatively large depth, the present application can achieve a channel length that satisfies the requirements of the gate-source capacitance.

In addition, since the junction depth of the body region of the present application is no longer limited by the magnitude of the gate-source capacitance, the body region of the present application can have a relatively large junction depth, and the relatively large junction depth can eliminate the adverse effects of surface defects in the super junction and thus improve the product yield.

### BRIEF DESCRIPTION OF THE DRAWINGS

The present application is described in detail below with reference to the drawings and specific implementations.

FIG. 1 is a schematic structural diagram of a super junction device in an embodiment of the present application.

FIGS. 2A-2H are schematic structural diagrams of the steps of a method for manufacturing a super junction device in an embodiment of the present application.

### DETAILED DESCRIPTION OF THE DISCLOSURE

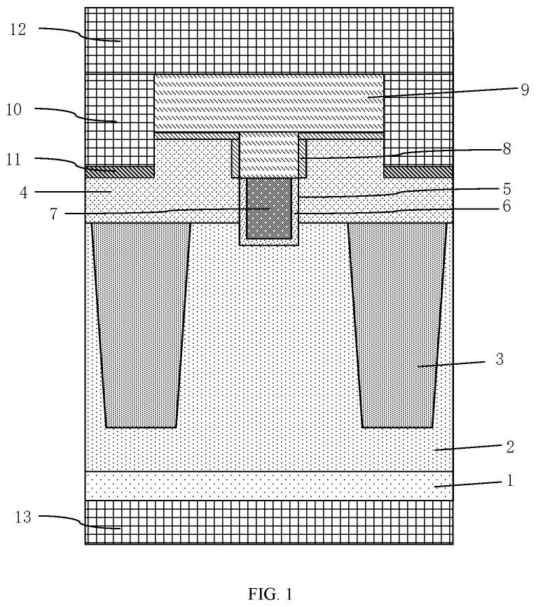

Referring to FIG. 1, which is a schematic structural diagram of a super junction device in an embodiment of the present application, a device unit region of the super junction device in this embodiment of the present application includes:

a super junction composed of P-type pillars 3 and N-type pillars arranged alternately, one of the P-type pillars 3 and an adjacent N-type pillar forming a super junction unit.

The P-type pillar 3 is formed by a P-type epitaxial layer filling a super junction trench, the N-type pillar is formed by a first N-type epitaxial layer 2 located between the P-type pillars 3, and the super junction trench is formed in the first N-type epitaxial layer 2. A P-type body region 4 is formed in the first N-type epitaxial layer 2.

Each super junction device unit further includes a gate structure, the gate structure being a trench gate including a gate trench 5, a gate dielectric layer 6 formed on the inner surface of the gate trench 5, and a polysilicon gate 7 filling the gate trench 5.

At least one side surface of the gate trench 5 is located in the N-type pillar, and the depth of the gate trench 5 is greater than the junction depth of the P-type body region 4.

The top surface of the gate trench 5 is level with the top surface of the super junction unit, and the top surface of the polysilicon gate 7 is etched back below the top surface of the gate trench 5.

A source region 8 is formed by an N+doped region which is formed by performing ion implantation on the side surface of the gate trench 5 on the top of the polysilicon gate 7 and on the surface of the P-type body region 4 outside the gate trench 5.

The surface of the P-type body region 4 at the bottom of the source region 8 and covered by the side surface of the polysilicon gate 7 is used to form a channel, the length of the channel is controlled by controlling the position of the top surface of the polysilicon gate 7 so as to control gate-source capacitance, and a larger distance between the top surface of the polysilicon gate 7 and the top surface of the gate trench 5 corresponds to a shorter channel and smaller gate-source capacitance.

In an example, the P-type body region 4 is formed by superimposing a first P-type doped region and a second P-type doped region, so as to increase the junction depth of the P-type body region 4.

The first P-type doped region is formed by means of ion implantation and annealing drive-in before the P-type pillar 3 is formed, the doping concentration and depth of the first P-type doped region are determined by corresponding ion implantation and annealing drive-in processes, and the annealing drive-in process of the first P-type doped region is not limited by process conditions of the super junction including the P-type pillar 3 such that the depth of the first P-type doped region can be increased, thereby increasing the junction depth of the P-type body region 4.

Before the polysilicon gate 7 is etched back, under the condition that the top surface of the polysilicon gate 7 is level with the top surface of the gate trench 5, the second P-type doped region is formed in the first P-type doped region on two sides of the gate structure by means of full ion implantation in a self-aligned manner, the full ion implantation for forming the second P-type doped region being used to adjust a threshold voltage for forming the channel.

A terminal region of the super junction device is formed on the periphery of the device unit region. The terminal region includes a P-type ring surrounding the device unit region. The first P-type doped region and the P-type ring have the same doped structure and are simultaneously formed by means of the same ion implantation and annealing drive-in processes. The junction depth of the P-type body region 4 is 1-5 micrometers. In an example, an implantation dose of the ion implantation for forming the first P-type doped region is greater than 2e13 cm⁻², and the junction depth of the P-type body region 4 is 3 micrometers.

In this embodiment, the first N-type epitaxial layer 2 is formed on the surface of a semiconductor substrate 1.

The semiconductor substrate 1 is a silicon substrate, the first N-type epitaxial layer 2 is a silicon epitaxial layer, and the P-type epitaxial layer of the P-type pillar 3 is a silicon epitaxial layer.

An N+ doped drain region is formed at the bottom of the first N-type epitaxial layer 2, and the drain region is formed by the thinned N+ doped semiconductor substrate 1 or formed by performing N+ back ion implantation on the thinned semiconductor substrate 1.

The device further includes an interlayer film 9, a contact 10, and a front metal layer 12. The interlayer film 9 is located in the gate trench 5 in a top region of the polysilicon gate 7.

The contact 10 is formed on the top of both the source region 8 and the polysilicon gate 7, and only the contact 10 on the top of the source region 8 is shown in FIG. 1. The bottom of the contact 10 on the top of the source region 8 passes through the source region 8 and contacts the P-type body region 4, and a contact region 11 composed of a P+ region is formed on the surface of the P-type body region 4 at the bottom of the contact 10 on the top of the source region 8.

A back metal layer 13 is formed on the back of the back-thinned semiconductor substrate 1, and a drain is composed of the back metal layer 13.

In this embodiment of the present application, the top surface of the polysilicon gate 7 is etched back below the top surface of the gate trench 5 and the source region 8 is formed on the side surface of the gate trench 5 on the top of the polysilicon gate 7 and on the surface of the P-type body region 4 outside the gate trench 5 in a self-aligned manner, so that the length of the channel can be controlled by adjusting the position of the top surface of the polysilicon gate 7. When the device is turned on, a channel composed of an inversion layer may be formed on the surface of the body region covered by the side surface of the polysilicon gate 7, since the channel length is a height of the area of the P-type body region 4 covered by the side surface of the polysilicon gate 7, the channel length will also decrease when height of the area of the P-type body region 4 covered by the side surface of the polysilicon gate 7 decreases. Since the source region 8 and the body region of the device are usually connected to the source, the polysilicon gate 7 is connected to the gate. Therefore, when the area of the body region covered by the side surface of the polysilicon gate 7 decreases, the parasitic capacitance between the gate and the source, i.e., the gate-source capacitance, decreases.

In an existing device, the polysilicon gate 7 usually passes through the body region completely, so the polysilicon gate 7 may fully cover the entire depth of the body region, in which case a deeper depth of the body region corresponds to larger gate-source capacitance. In this embodiment of the present application, the channel length is achieved by etching back the polysilicon gate 7, so that the adjustment of the channel length can be independent of the adjustment of the depth of the body region. Therefore, the gate-source capacitance of the device can be controlled by adjusting the channel length, that is, even if the body region has a relatively large depth, the present application can achieve a channel length that satisfies the requirements of the gate-source capacitance.

In addition, since the junction depth of the body region in this embodiment of the present application is no longer limited by the magnitude of the gate-source capacitance, the body region of the present application can have a relatively large junction depth, and the relatively large junction depth can eliminate the adverse effects of surface defects in the super junction and thus improve the product yield.

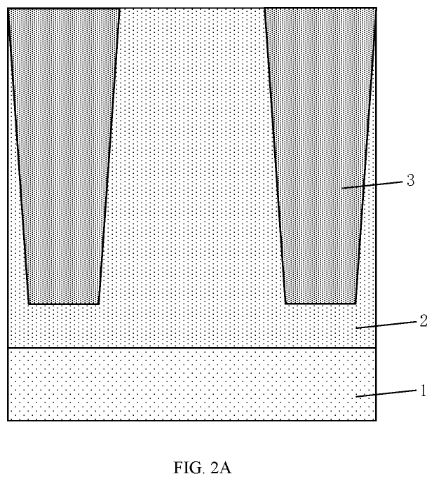

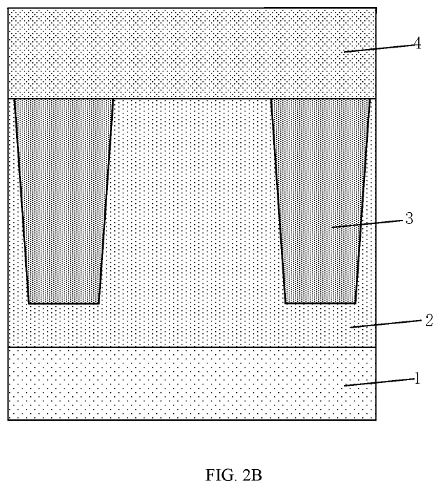

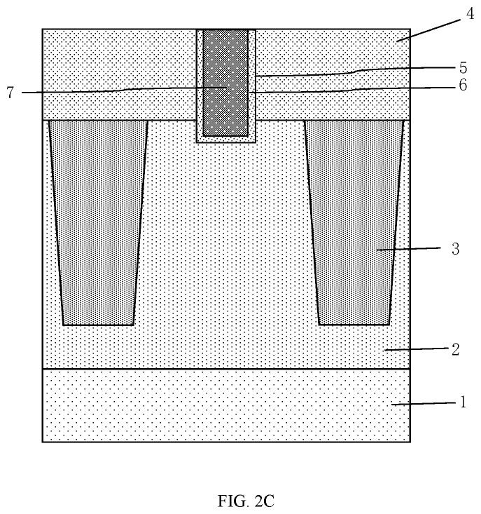

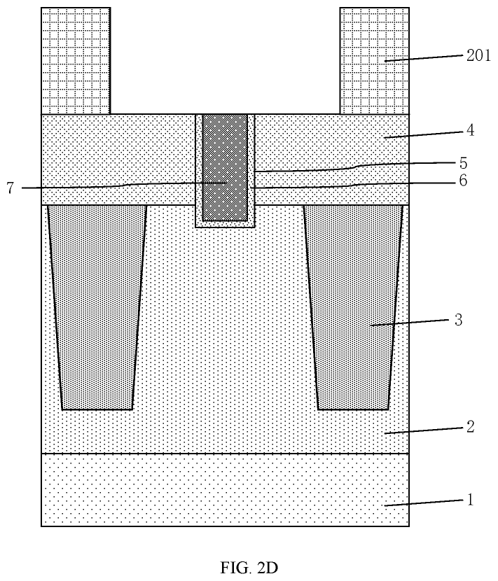

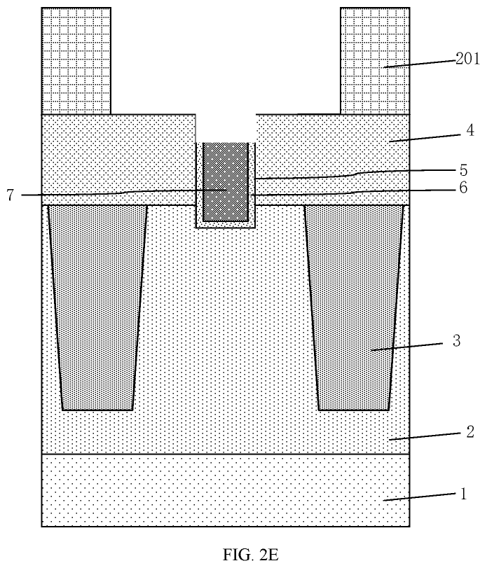

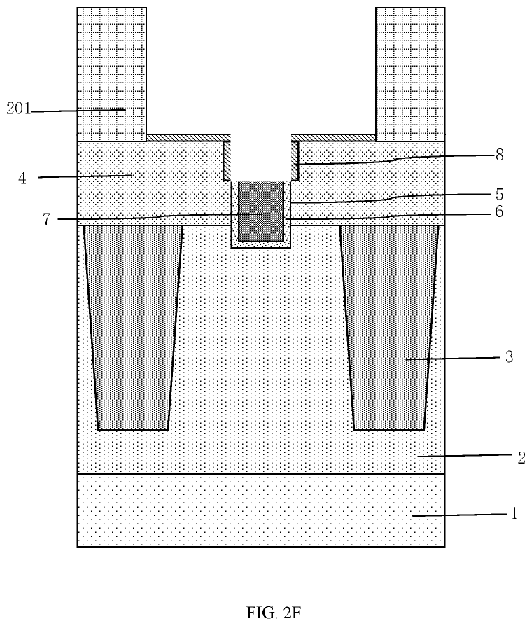

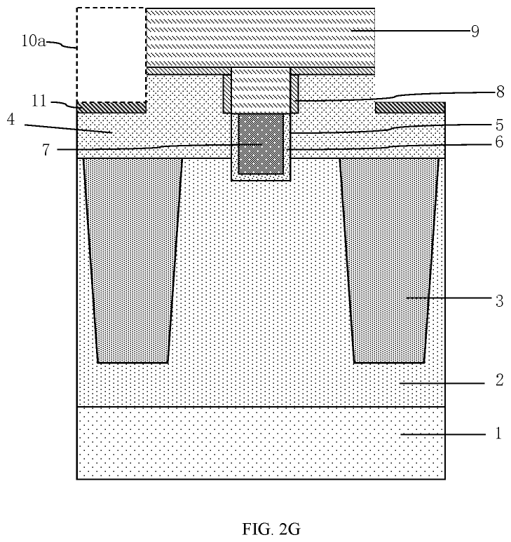

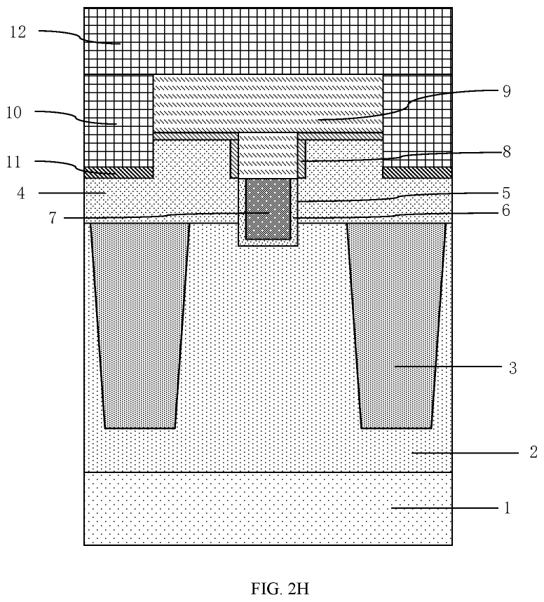

Referring to FIGS. 2A-2H, which are schematic structural diagrams of the steps of a method for manufacturing a super junction device in an embodiment of the present application, in the method for manufacturing a super junction device provided by this embodiment of the present application, steps of forming a device unit region of the super junction device includes the following.

Step 1. A super junction trench is formed in a first N-type epitaxial layer 2, the super junction trench is filled with a P-type epitaxial layer to form a P-type pillar 3, the first N-type epitaxial layer 2 located between the P-type pillars 3 forming an N-type pillar.

The P-type pillars 3 and the N-type pillars are arranged alternately to form a super junction, and one of the P-type pillars 3 and an adjacent N-type pillar form a super junction unit.

In the method provided by this embodiment of the present application, the first N-type epitaxial layer 2 is formed on the surface of a semiconductor substrate 1.

The semiconductor substrate 1 is a silicon substrate, the first N-type epitaxial layer 2 is a silicon epitaxial layer, and the P-type epitaxial layer of the P-type pillar 3 is a silicon epitaxial layer.

Step 2. Referring to FIG. 2B, a P-type body region 4 is formed in the first N-type epitaxial layer 2.

Step 3. Referring to FIG. 2C, a gate structure corresponding to each super junction device unit is formed, the gate structure being located on the top of the corresponding super junction unit, and the gate structure being a trench gate. Sub-steps of forming the gate trench 5 includes the following:

Step 31. Referring to FIG. 2C, the gate trench 5 is formed, at least one side surface of the gate trench 5 being located in the N-type pillar, the depth of the gate trench 5 being greater than the junction depth of the P-type body region 4, and the top surface of the gate trench 5 being level with the top surface of the super junction unit.

Step 32. Referring to FIG. 2C, a gate dielectric layer 6 is formed on the inner surface of the gate trench 5.

In the method provided by this embodiment of the present application, the gate dielectric layer 6 is a gate oxide layer formed by means of a thermal oxidation process.

Step 33. Referring to FIG. 2C, the gate trench 5 is filled with a polysilicon gate 7, the top surface of the polysilicon gate 7 being level with the top surface of the gate trench 5.

Step 34. Referring to FIG. 2D, a mask layer pattern 201 is formed to define a formation region of a source region 8, each gate trench 5 being located in the formation region of the source region 8. The mask layer pattern 201 is generally formed by means of a photoresist pattern.

Step 35. Referring to FIG. 2E, each polysilicon gate 7 is etched back by using the mask layer pattern 201 as a mask such that the top surface of the polysilicon gate 7 is lower than the top surface of the gate trench 5, the gate dielectric layer 6 and the polysilicon gate 7 filling the gate trench 5 being superimposed to form the trench gate.

Step 4. Referring to FIG. 2F, N+ion implantation is performed to form a source region 8 on the side surface of the gate trench 5 on the top of the polysilicon gate 7 and on the surface of the P-type body region 4 outside the gate trench 5. Then, the mask layer pattern 201 is removed.

The surface of the P-type body region 4 at the bottom of the source region 8 and covered by the side surface of the polysilicon gate 7 is used to form a channel, the length of the channel is controlled by controlling the position of the top surface of the polysilicon gate 7 so as to control gate-source capacitance, and a larger distance between the top surface of the polysilicon gate 7 and the top surface of the gate trench 5 corresponds to a shorter channel and smaller gate-source capacitance.

In an example, the P-type body region 4 is formed by superimposing a first P-type doped region and a second P-type doped region, so as to increase the junction depth of the P-type body region 4. The step of forming the P-type body region 4 in step 2 is divided into:

performing ion implantation and annealing drive-in to form the first P-type doped region before the formation of the super junction trench in step 1, and adjusting the doping concentration and depth of the first P-type doped region by means of ion implantation and annealing drive-in processes. The annealing drive-in process of the first P-type doped region being not limited by process conditions of the super junction including the P-type pillar 3 such that the depth of the first P-type doped region can be increased, thereby increasing the junction depth of the P-type body region 4.

After step 33 and before step 34, full ion implantation is performed to form the second P-type doped region in the first P-type doped region on two sides of the gate structure in a self-aligned manner.

A terminal region of the super junction device is formed on the periphery of the device unit region. The terminal region includes a P-type ring surrounding the device unit region.

The first P-type doped region and the P-type ring are simultaneously formed by means of the same ion implantation and annealing drive-in processes. The junction depth of the P-type body region 4 is 1-5 micrometers. In an example, an implantation dose of the ion implantation for forming the first P-type doped region is greater than 2e13 cm⁻², and the junction depth of the P-type body region 4 is 3 micrometers.

The method further includes the following front device process steps.

Referring to FIG. 2G, an interlayer film 9 is formed. The interlayer film 9 is located in the gate trench 5 in a top region of the polysilicon gate 7.

An opening 10a of a contact 10 is formed. The contact 10 is formed on the top of both the source region 8 and the polysilicon gate 7, and only the opening 10a of the contact 10 on the top of the source region 8 is shown in FIG. 2G. The bottom of the opening 10a of the contact 10 on the top of the source region 8 passes through the source region 8 and contacts the P-type body region 4.

After the opening 10a of the contact 10 is formed, a contact region 11 is formed on the surface of the P-type body region 4 at the bottom of the contact 10 on the top of the source region 8 by means of P+ ion implantation.

Referring to FIG. 2H, the contact 10 is formed by filling the opening 10a with a metal layer. The front metal layer 12 is formed, and the front metal layer 12 is patterned to form a source and a gate composed of the patterned front metal layer 12.

Then, a back process is performed, including:

referring to FIG. 1, forming an N+ doped drain region at the bottom of the first N-type epitaxial layer 2, the step of forming the drain region including: directly forming the drain region by thinning the N+ doped semiconductor substrate 1, or forming the drain region by thinning the semiconductor substrate 1 and then performing N+ back ion implantation on the thinned semiconductor substrate 1.

A back metal layer 13 is formed on the back of the back-thinned semiconductor substrate 1, and a drain is composed of the back metal layer 13.

The present application is described in detail above via specific embodiments, which, however, are not intended to limit the present application. Without departing from the principles of the present application, those skilled in the art can also make many modifications and improvements, which should also be regarded as the protection scope of the present application.

What is claimed is:

1-15. (canceled)

16. A super junction device, wherein a device unit region of the super junction device comprises:
a super junction composed of P-type pillars and N-type pillars arranged alternately, one of the P-type pillars and an adjacent N-type pillar forming a super junction unit;
the P-type pillar is formed by a P-type epitaxial layer filling a super junction trench, the N-type pillar is formed by a first N-type epitaxial layer located between the P-type pillars, and the super junction trench is formed in the first N-type epitaxial layer; a P-type body region is formed in the first N-type epitaxial layer;
each super junction device unit further comprises a gate structure, the gate structure being a trench gate comprising a gate trench, a gate dielectric layer formed on the inner surface of the gate trench, and a polysilicon gate filling the gate trench;
at least one side surface of the gate trench is located in the N-type pillar, and the depth of the gate trench is greater than the junction depth of the P-type body region;
the top surface of the gate trench is level with the top surface of the super junction unit, and the top surface of the polysilicon gate is etched back below the top surface of the gate trench;
a source region is formed by an N+ doped region which is formed by performing ion implantation on the side surface of the gate trench on the top of the polysilicon gate and on the surface of the P-type body region outside the gate trench; and
the surface of the P-type body region at the bottom of the source region and covered by the side surface of the polysilicon gate is used to form a channel, the length of the channel is controlled by controlling the position of the top surface of the polysilicon gate so as to control gate-source capacitance, and a larger distance between the top surface of the polysilicon gate and the top surface of the gate trench corresponds to a shorter channel and smaller gate-source capacitance.

17. The super junction device according to claim 16, wherein the P-type body region is formed by superimposing a first P-type doped region and a second P-type doped region, so as to increase the junction depth of the P-type body region;
the first P-type doped region is formed by means of ion implantation and annealing drive-in before the P-type pillar is formed, the doping concentration and depth of the first P-type doped region are determined by corresponding ion implantation and annealing drive-in processes, and the annealing drive-in process of the first P-type doped region is not limited by process conditions of the super junction comprising the P-type pillar such that the depth of the first P-type doped region can be increased, thereby increasing the junction depth of the P-type body region; and
before the polysilicon gate is etched back, under the condition that the top surface of the polysilicon gate is level with the top surface of the gate trench, the second P-type doped region is formed in the first P-type doped region on two sides of the gate structure by means of full ion implantation in a self-aligned manner, the full ion implantation for forming the second P-type doped region being used to adjust a threshold voltage for forming the channel.

18. The super junction device according to claim 17, wherein a terminal region of the super junction device is formed on the periphery of the device unit region; the terminal region comprises a P-type ring surrounding the device unit region, the first P-type doped region and the P-type ring have the same doped structure and are simultaneously formed by means of the same ion implantation and annealing drive-in processes, and the junction depth of the P-type body region is 1-5 micrometers.

19. The super junction device according to claim 18, wherein the first N-type epitaxial layer is formed on the surface of a semiconductor substrate.

20. The super junction device according to claim 19, wherein the semiconductor substrate is a silicon substrate, the first N-type epitaxial layer is a silicon epitaxial layer, and the P-type epitaxial layer of the P-type pillar is a silicon epitaxial layer.

21. The super junction device according to claim 16, wherein an N+doped drain region is formed at the bottom of the first N-type epitaxial layer, and the drain region is formed by the thinned N+ doped semiconductor substrate or formed by performing N+ back ion implantation on the thinned semiconductor substrate.

22. The super junction device according to claim 18, wherein an implantation dose of the ion implantation for forming the first P-type doped region is greater than 2e13 cm⁻², and the junction depth of the P-type body region is 3 micrometers.

23. A method for manufacturing a super junction device, wherein steps of forming a device unit region of the super junction device comprises:
step 1, forming a super junction trench in a first N-type epitaxial layer, filling the super junction trench with a P-type epitaxial layer to form a P-type pillar, the first N-type epitaxial layer located between the P-type pillars forming an N-type pillar,
the P-type pillars and the N-type pillars being arranged alternately to form a super junction, and one of the P-type pillars and an adjacent N-type pillar forming a super junction unit;
forming a P-type body region in the first N-type epitaxial layer;
forming a gate structure corresponding to each super junction device unit, the gate structure being located on the top of the corresponding super junction unit, the gate structure being a trench gate, and sub-steps of forming the gate trench comprising:
forming the gate trench, at least one side surface of the gate trench being located in the N-type pillar, the depth of the gate trench being greater than the junction depth of the P-type body region, and the top surface of the gate trench being level with the top surface of the super junction unit;
forming a gate dielectric layer on the inner surface of the gate trench;
filling the gate trench with a polysilicon gate, the top surface of the polysilicon gate being level with the top surface of the gate trench;
forming a mask layer pattern to define a formation region of a source region, each gate trench being located in the formation region of the source region; and
etching back each polysilicon gate by using the mask layer pattern as a mask such that the top surface of the polysilicon gate is lower than the top surface of the gate trench, the gate dielectric layer and the polysilicon gate filling the gate trench being superimposed to form the trench gate; and
performing N+ ion implantation to form a source region on the side surface of the gate trench on the top of the polysilicon gate and on the surface of the P-type body region outside the gate trench, the surface of the P-type body region at the bottom of the source region and covered by the side surface of the polysilicon gate being used to form a channel, the length of the channel being controlled by controlling the position of the top surface of the polysilicon gate so as to control gate-source capacitance, and a larger distance between the top surface of the polysilicon gate and the top surface of the gate trench corresponding to a shorter channel and smaller gate-source capacitance.

24. The method for manufacturing a super junction device according to claim 23, wherein the P-type body region is formed by superimposing a first P-type doped region and a second P-type doped region, so as to increase the junction depth of the P-type body region; wherein the step of forming the P-type body region in the first N-type epitaxial layer is divided into:
performing ion implantation and annealing drive-in to form the first P-type doped region before the formation of the super junction trench, and adjusting the doping concentration and depth of the first P-type doped region by means of ion implantation and annealing drive-in processes, the annealing drive-in process of the first P-type doped region being not limited by process conditions of the super junction comprising the P-type pillar such that the depth of the first P-type doped region can be increased, thereby increasing the junction depth of the P-type body region; and
after filling the gate trench with a polysilicon gate and before forming a mask layer pattern to define a formation region of a source region, performing full ion implantation to form the second P-type doped region in the first P-type doped region on two sides of the gate structure in a self-aligned manner.

25. The method for manufacturing a super junction device according to claim 24, wherein a terminal region of the super junction device is formed on the periphery of the device unit region;
the terminal region comprises a P-type ring surrounding the device unit region;
the first P-type doped region and the P-type ring are simultaneously formed by means of the same ion implantation and annealing drive-in processes; and the junction depth of the P-type body region is 1-5 micrometers.

26. The method for manufacturing a super junction device according to claim 25, wherein the first N-type epitaxial layer is formed on the surface of a semiconductor substrate.

27. The method for manufacturing a super junction device according to claim 26, wherein the semiconductor substrate is a silicon substrate, the first N-type epitaxial layer is a silicon epitaxial layer, and the P-type epitaxial layer of the P-type pillar is a silicon epitaxial layer.

28. The method for manufacturing a super junction device according to claim 25, wherein an implantation dose of the ion implantation for forming the first P-type doped region is greater than 2e13 cm⁻², and the junction depth of the P-type body region is 3 micrometers.

29. The method for manufacturing a super junction device according to claim 23, further comprising a step of forming an N+ doped drain region at the bottom of the first N-type epitaxial layer,
the drain region being directly formed by thinning the N+ doped semiconductor substrate, or
the drain region being formed by thinning the semiconductor substrate and then performing N+ back ion implantation on the thinned semiconductor substrate.

30. The method for manufacturing a super junction device according to claim 23, wherein the gate dielectric layer is a gate oxide layer formed by means of a thermal oxidation process.
